(19) United States
(12) Patent Application Publication
(10) Pub. No.: US 2010/0194410 A1
(43) Pub. Date: Aug. 5, 2010

(54) SENSOR FOR SENSING AN ANALYTE AND COMBINATION OF THE SENSOR AND AN OPTICAL READER

(76) Inventors: Thomas Alexander FORD, Oxford (GB); Antony Robert Glauser, Oxford (GB)

Correspondence Address: MARK D. SARALINO ( SHARP );RENNER, OTTO, BOISSELLE & SKLAR, LLP, 1621 EUCLID AVENUE, 19TH FLOOR, CLEVELAND, OH, 44115, US

(21) Appl. No.: 12/694,324

(22) Filed: Jan. 27, 2010

(30) Foreign Application Priority Data
Jan. 30, 2009 (GB) 0901499.4

(51) Int. Cl. G01R 27/08

(52) U.S. Cl. 324/693; 324/96

(57) ABSTRACT

A sensor array for detecting the content of a fluid sample comprises first and second electrodes having connections for a drive signal. The first electrode is coated with a layer of a first material having optical properties which change according to the electrical charge passing through it or the potential across it. Sensor sites are defined by islands of a second material such that the charge passing through or the potential across the second material, in response to the drive signal, varies according to the fluid sample composition.

This Nonprovisional application claims priority under 35 U.S.C. §119(a) on Patent Application No. 0901499.4 filed in the United Kingdom on Jan. 30, 2009, the entire contents of which are hereby incorporated by reference.

### FIELD OF THE INVENTION

The present invention relates to a sensor for sensing an analyte of a sample. Such a sensor may be used for detecting the chemical or biological content of fluids. Understanding the chemical or biological content of fluids is important in such fields as healthcare, industrial process control and environmental monitoring. Such a sensor may comprise a sensor array whereby a single sensor array is able to independently measure a multitude of different analytes in a single fluid. The present invention also relates to a combination of such a sensor and an optical reader.

### BACKGROUND OF THE INVENTION

Sensor arrays are often used to determine biological or chemical content of fluids. For example, there exist a number of arrays designed to independently detect many different DNA strands of particular sequences, for example the Nanochip (Nanogen) and the Genechip (Affymetrix). There are also arrays designed to detect many different protein molecules, for example the ProtoArray (invitrogen) and Panorama (Sigma Aldrich) or to detect different constituents of blood, for example the I-Stat chip (Abbott).

There exist a number of different methods utilised by sensors to detect the presence of particular analytes. In particular, the analyte of interest may be detected by a change in the electrical properties of an electrode in contact with the fluid bearing the analyte. There are a wide range of different electrical methods that can be exploited to detect an analyte. These include monitoring the uptake or release of electrical charge due to electrochemical reactions involving the analyte. These also include monitoring the change in the small signal electrical properties of a sensitized electrode, for example electrical impedance, as the electrode and analyte interact.

A sensor array may consist of a large number of sensing pixels with arrays of 5-10,000 pixels being known in the art. An example is disclosed in FIG. 1 of the accompanying drawings. The sensor array 1 is formed on a piece of glass, plastic or other material in the form of a sensor chip. In order to carry out electrical sensing, the electrical current flowing at each sensor pixel must be measured individually. This measurement is typically carried out by a reader device 2 which is separate from the sensor array. Therefore the sensor chip itself must have a plurality of electrical interconnects 3 which allow the reader device to connect electrically to each pixel. Similar systems are described in, for example, U.S. Pat. No. 5,837,454 (published on 17 Nov. 1998), U.S. Pat. No. 5,871,918 (published on 16 Feb. 1999), U.S. Pat. No. 6,017,696 (published on 25 Jan. 2000) and U.S. Pat. No. 7,172,897 (published on 6 Feb. 2007).

The chip shown in FIG. 1 has a number of problems which limit its usefulness in mass market applications which require a cheap, disposable sensor chip. These problems are due to the fact that the chip bears a large number of off-chip electrical interconnects.

Electrical connection must be made between each interconnect 3 and an electrode 4 within the reader device 2. The electrical interconnects are likely to be small in size and there is a considerable risk of mechanical failure of a connection or failure to align the chip correctly such that all electrical connections are made. The difficulty of alignment may lead to a skilled operator being required and prevent home use of the device.

The large number of interconnects increases the manufacturing cost of the chip due to materials, patterning and tooling costs. The interconnects may also require plating with gold. The increased complexity of manufacture may also decrease yield. Furthermore, the large number of interconnects requires a larger chip area, further increasing costs.

Electrical interconnects carrying signal currents are also prone to disruption by electrical short-circuiting, whereby fluid residues may form a partially conducting bridge between adjacent interconnect lines. The chip and reader must be placed in close contact in order to make an electrical connection and this risks spreading harmful contamination from the fluid to the reader, particularly where biological fluids such as blood are used.

The problem of a plurality of electrical interconnects has been previously addressed in several ways. One approach is to form “pixels” at the intersections of row and column electrodes as disclosed in FIG. 2 of the accompanying drawings. A pixel 5 is formed at the intersection between a row electrode 6 and a column electrode 7. Each row electrode has an off-chip interconnect 8 and each column electrode has an off-chip interconnect 9. In this way the number of interconnects for n pixels can be reduced to 2√n. This approach is described, for example in U.S. Pat. No. 5,846,708 (published on 8 Dec. 1998). However, even a modest sized array of 100 pixels still requires 20 off-chip interconnects in this approach.

Another approach to reduce the number of electrical interconnects is to add electrical multiplexing circuits onto the sensor chip itself. Such a process is described, for example, in U.S. Pat. No. 5,846,708, U.S. Pat. No. 5,891,630 (published on 6 Apr. 1999) U.S. Pat. No. 7,150,997 (published on 19 Dec. 2006), U.S. Pat. No. 7,172,897. In these approaches, each multiplexing circuit has a small number of off-chip interconnects and permits electrical measurement of a larger number of pixels. The use of multiplexing circuits can reduce the number of off-chip interconnects required to a small amount, alleviating some of the reliability and alignment difficulties. However, integration of electrical circuits, of either traditional CMOS type or using a thin-layer of polysilicon, adds greatly to the cost and complexity of each chip.

Therefore there remains a need for a low-cost method of reducing the number of off-chip interconnects in order to produce a cheap, disposable sensor array chip for mass market application.

### SUMMARY OF THE INVENTION

According to a first aspect of the invention, there is provided a sensor for sensing an analyte of a sample, comprising at least one sensor site, the or each of which comprises first and second materials disposed between first and second electrodes arranged to receive electricity, the second material being arranged to contact the sample and to vary, in response to the electricity, the charge passing through or the potential across the second material in accordance with the presence or quantity of the analyte in the sample, the first material having an optical property whose value is a function of the charge passing through or the potential across the first material.

The first and second materials may be electrically in series between the first and second electrodes.

At least one of the first and second electrodes may be transparent.

The first and second electrodes may be connected to a wireless electricity receiver. The wireless receiver may comprise a coil for inductive coupling to an electricity source.

The sample may be a fluid sample.

The sensor may comprise a plurality of sensor sites. The sensor sites may be sensitive to a plurality of different analytes. At least some of the first electrodes may be connected together. The at least some first electrodes may comprise portions of a common unpatterned electrode. One of the first and second materials may comprise a layer formed on the common unpatterned electrode. The other of the first and second materials may be formed as islands on the one of the first and second materials defining the sensor sites.

The first and second electrodes may be interdigitated at the or each sensor site. The first and second electrodes may be coated with the first and second materials, respectively.

The first and second electrodes may be spaced apart to provide access to the second material for the sample. At least one of the first and second electrodes may define holes for passage of the sample. The sensor may comprise a gel or a solid disposed between the first and second electrodes for permitting diffusion of the or each analyte.

According to a second aspect of the invention, there is provided a combination of a sensor according to the first aspect of the invention and an optical reader for reading the value of the optical property.

The optical reader may comprise a radiation source for irradiating the first material with optical radiation and a detector for detecting the value of the optical property. The optical radiation may be at least one of infrared radiation, visible light and ultraviolet radiation.

It is thus possible to provide a sensor array comprising one or more sensor sites. In one embodiment, each sensor site comprises at least two electrodes in contact with a common fluid sample. The first electrode is coated with a layer of a first material that changes optical properties according to the electrical charge passing through it or the potential across it. The first or second electrode is coated with a layer of a second material which is biologically or chemically sensitive such that the charge passing through it or potential across it varies, in response to an applied drive signal, according to the composition of the fluid sample.

Since the first and second material are within the same electrical circuit formed by the electrodes, the electrical charge passing through the first material or potential across it is affected by the electrical properties of the second material, which are affected by the content of the fluid. Since the optical properties of the first material depend upon the electrical charge passing through it or potential across it, the optical properties of the first material are indicative of the content of the fluid.

The optical properties of the first material at each sensor site in the array may be measured optically. From this measurement, the sensor response at each site is ascertained. In this way, information as to the content of the fluid can be deduced.

An electrical drive signal is applied to the sensor array in order for it to function. Optionally, each first electrode from each sensor site may be connected to each other first electrode. In this way, the drive signal may be applied simultaneously to all of the first electrodes within the array via a single interconnect. Furthermore, each second electrode from each sensor site may be connected to each other second electrode. In this way, the number of interconnects required to drive all of the electrodes in the device may be reduced to as few as two. This does not prevent the material between the first and second electrodes from behaving differentially from one sensor site to the next, providing the electrical coupling through the fluid, or through the first and second material layers, is imperfect. This may be achieved by some form of physical partitioning of the sensor sites or, in a particularly simple implementation, by making the gap between the electrodes sufficiently small relative to the size and/or spacing of the sensor sites. The limiting case for such a configuration is that each electrode array merges with the interconnection, forming two opposing uniform sheets of conductive material, with the individual sensor sites being defined by the differential deposition of varying compositions of the second material.

The drive signal may be transferred to the sensor array wirelessly.

The first material is not required to have a specific chemical or biological response to the composition of the fluid sample, instead serving only as an indicator of the charge passing through it or potential across it. The first material is also not required to be in direct contact with the second material.

Either the first or second material or both may be embedded within or comprise part of an electrode, provided that they are in contact with the analyte-bearing fluid.

It is thus possible to provide a technique whereby a material which changes its optical properties in response to a change to the electrical charge passing through it or potential across it is added to each site in a sensor array. The electrical response of each sensor site is thereby transduced into an optical signal. The optical signal at each site can then be read out optically.

Since the array is read optically, measuring an electrical signal at each site is not necessary. Therefore the necessity of having a plurality of off-chip interconnect electrodes, as described in the prior art, is removed. The number of interconnects is reduced to a minimum of two, those providing electrical power. Eliminating the vast majority of the interconnects improves mechanical reliability, makes manufacture less costly, increases yield and allows the sensor array to be used by non-skilled personnel. Furthermore, it is not necessary to utilise on-chip multiplexing circuitry, as seen in the prior art, to achieve the reduction in interconnects. Eliminating on-chip multiplexing circuitry makes manufacture less costly and increases yield.

It is possible to provide a low cost method of achieving optical readout of the sensor array. This therefore permits the manufacture of a cheap, disposable sensor array chip, suitable for home use. Such a chip has the advantage of mass market sales.

An electrical drive signal is transmitted to the sensor chip from a separate device. In an embodiment of the invention, the drive signal is transmitted wirelessly so that there is no need for the sensor chip and device to be in intimate contact. This is advantageous since any contamination, for example by blood, is not passed from the sensor chip to the device.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a schematic diagram of a sensor chip and reader from the prior art.

FIG. 2 is a schematic diagram of a row and column addressed sensor chip from the prior art.

FIG. 3 shows the design of a sensor chip with one unpatterned electrode coated with a first material and one unpatterned electrode with islands of a second material.

FIG. 4 is a simplified equivalent circuit diagram of a sensor site using impedance spectroscopy to electrically detect an analyte in a fluid.

FIG. 5 is a simplified equivalent circuit diagram of a sensor site using electrochemical reactions to electrically detect an analyte in a fluid.

FIG. 6 shows an optical geometry for imaging a sensor chip in transmission or fluorescence.

FIG. 7 shows an optical geometry for imaging a sensor chip in reflection or fluorescence.

FIG. 8 shows how an image sensor may be controlled by a computing device which also analyses an image.

FIG. 9 shows the design of a sensor chip with two unpatterned electrodes, one coated with a first material and with islands of a second material deposited on top.

FIG. 10 shows the design of a sensor chip with two unpatterned electrodes, one or both coated with a first material and one or both with islands of second material deposited on top.

FIG. 11 shows the design of a sensor chip with one electrode with a second material deposited on top and multiple electrodes coated with a first material.

FIG. 12 shows the design of a sensor chip with one or both electrodes patterned to delimit pixels.

FIG. 13 shows the design of a sensor chip with both electrodes patterned, one electrode having pixels coated with multiple compositions of a first material.

FIG. 14 shows the design of a sensor chip with one electrode patterned to form pixels comprising interdigitated electrodes.

FIG. 15 shows the design of a sensor chip with multiple off-chip interconnects each connected to one or more pixels.

FIG. 16 shows the design of a sensor chip with an aerial for wireless reception of drive signals.

FIG. 17 shows the design of a sensor chip consisting of two electrodes, one with an aerial for wireless reception which is connected by a wire to the other electrode.

FIG. 18 shows the design of a sensor chip with porous electrodes.

FIG. 19 shows the design of a sensor chip filled with an electrolyte-bearing gel.

FIG. 20 shows the design of a sensor chip for deployment in a flow cell.

FIG. 21 shows the design of a sensor pixel used in Example 1.

FIG. 22 is a schematic diagram of a proprietary chemical binding to an electrode with a silver surface.

FIG. 23 shows that the progress of a reaction between a chemical and a chemically sensitive second material can be monitored by the transmission of light through a first material.

FIG. 24 shows that a component of the optical transmission of the first material corresponds to the resistance of the sensor pixel.

FIG. 25 shows that a component of the optical transmission of the first material corresponds to the capacitance of the sensor pixel.

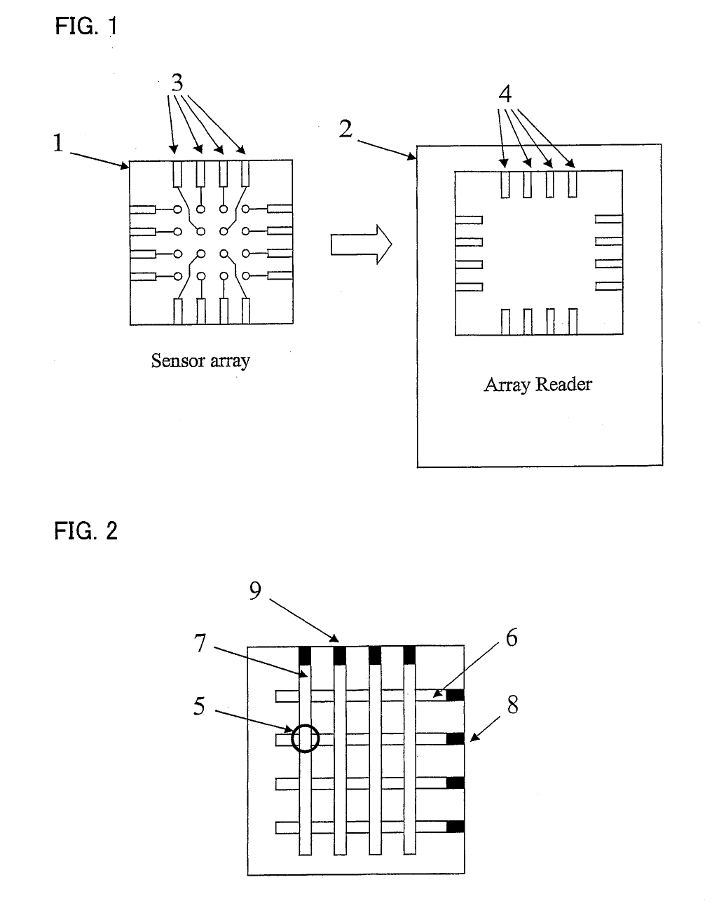

The term “unpatterned electrode” refers to a flat, continuous sheet of conductor into which no insulating regions have been defined.

### DESCRIPTION OF THE EMBODIMENTS

### Embodiment 1

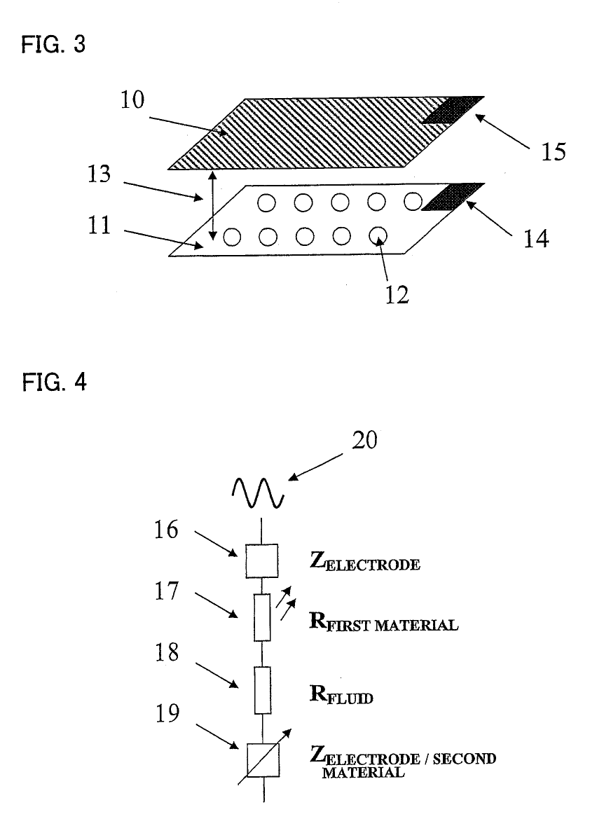

FIG. 3 illustrates the construction of a sensor array chip constituting a first embodiment of the invention. Electrodes 10 and 11 are continuous pieces of conductive material. At least one of the electrodes 10 and 11 is transparent. Suitable electrode materials include metals, conducting metal oxides, alloys, semiconductors and other materials known in the art. Suitable transparent electrode materials include indium tin oxide (ITO), other conducting metal oxides and other materials known in the art.

The electrode 10 is coated with a layer of a first material which has optical properties that change according to the electrical charge passing through it or the potential across it. The first material is preferably a material known to be electrochromic, including conducting polymers, for example polyaniline, polypyrrole and polythiophene, transition metal oxides, organometallic complexes and other electrochromic materials known in the art. However, any material that shows a change in optical properties in response to electrical charge flow or potential may be suitable. The first material may be deposited by spin coating, electropolymerization, drop casting, screen printing, stamping, evaporation or other suitable deposition method known in the art.

A number of islands 12 of the second material are deposited on the electrode 11, forming sensor sites. Each second material is biologically or chemically sensitive such that the charge passing through it or potential across it, in response to an applied drive signal, varies according to the composition of the fluid sample. Each island may comprise a different second material to form an array of sensor sites for different analytes. The second material may comprise any material that associates with any component of the analyte-bearing fluid. Such materials include but are not limited to metals, semiconductors, insulators, composite materials, chemical or biological materials or systems such as biological cells. Composite materials include those where a redox mediator compound is included. Composite materials may also include chemical systems dispersed in or bound to sol-gel matrices or polymers, including electroactive polymers or polyelectrolytes. Deposition of the second material may be achieved by drop casting, screen printing, inkjet printing, electrodeposition, stamping, mask evaporation or other suitable deposition method known in the art.

Since each electrode is a common continuous, unpatterned conductor, the individual sensor sites are defined by the presence of the islands of the second material 12 disposed over portions of the electrode 11. In order that each sensor site may operate independently from its neighbours the separation 13 between the electrodes must be sufficiently small relative to the size and/or spacing of the islands 12.

The two electrodes may be held apart at a fixed distance by spacers of an inert plastic, by being held rigid in a frame or by any other method. The analyte-bearing fluid to be analysed is introduced between the electrodes. The fluid may fill the cell by injection, pumping, diffusion, capillary filling or other method.

Interconnects 14 and 15 are connected to the reader device which applies the electrical drive signal. The interconnects 14 and 15 may be placed at any point on the edge of the sensor chip and may be of any size. The drive signal preferably comprises a static, single sequence or cyclical waveform. Any of the wide range of electrical and electrochemical sensing techniques known in the art may be used to detect the analyte at each sensor site. Particularly suitable techniques include impedance spectroscopy, chronoamperometry, cyclic voltammetry, linear-sweep voltammetry, AC voltammetry and tensammetry.

A simplified equivalent electrical circuit for each sensor site is illustrated in FIG. 4 for an example where impedance spectroscopy is used to monitor the reaction between an analyte and a second material. Impedance 16 represents the impedance (Z_{ELECTRODE}) of the electrode 10. Resistance 17 represents the resistance (R_{FIRST MATERIAL}) of the first material. Resistance 18 represents the resistance (R_{FLUID}) of the fluid. Impedance 19 represents the impedance (Z_{ELECTRODE}) of a portion of electrode 11 covered with an island of the second material 12. A drive signal 20 is applied. A reaction occurring between the second material 12 and an analyte in the fluid alters the impedance 19. The charge passing through first material resistance 17 or the voltage across it therefore varies as the impedance 19 changes. This leads to a change in the optical signal from the first material as the reaction between the second material 12 and an analyte in the fluid occurs.

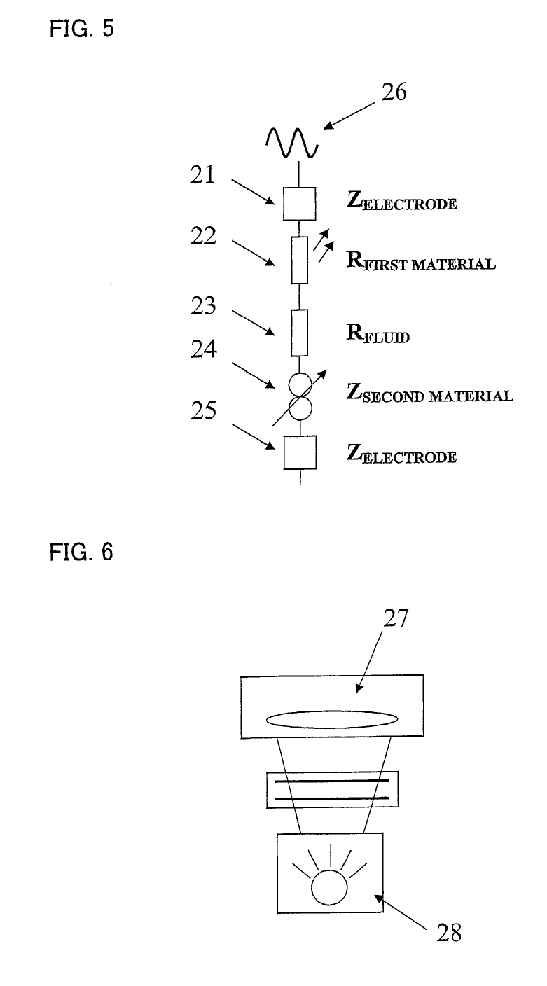

A simplified equivalent electrical circuit for each sensor site is illustrated in FIG. 5 for an example where an electrochemical reaction between an analyte and a second material produces an electrical current. Impedance 21 represents the impedance (Z_{ELECTRODE}) of the electrode 10. Resistance 22 represents the resistance (R_{FIRST MATERIAL}) of the first material. Resistance 23 represents the resistance (R_{FLUID}) of the fluid. Current source 24 represents current due to electrochemical reactions occurring between the second material and an analyte in the fluid (equivalent to an impedance Z_{SECOND MATERIAL}). Impedance 25 represents the impedance (Z_{ELECTRODE}) of the electrode 11. A drive signal 26 is applied. The charge passing through the first material resistance 22 or the voltage across it varies as the current due to electrochemical reactions 24 changes. This leads to a change in the optical signal from the first material.

The optical property of the first material that changes in response to charge flow or potential applied across it is preferably transmission, reflectance or fluorescence. This may be a change in the absolute value of transmission or reflectance or absolute intensity of fluorescence or a change in the spectral form of the property. Other optical properties that may vary in response to charge flow or applied potential include scattering, rotation of polarized light, second and third-harmonic generation and others known in the art.

FIG. 6 illustrates a possible transmission optical geometry for interrogating the sensor chip suitable for transparent electrodes. An image sensor 27 forms part of an optical reader and comprises a CCD (charge coupled device), CMOS (complementary metal oxide silicon) imager, photodiode array or similar imaging device capable of measuring the intensity of light emanating from the sensor array. The image sensor 27 may include a series of lenses so as to image the sensor array onto a detector of appropriate size. The image sensor 27 may include a microscope. The image sensor 27 may also include filters or gratings in order to provide spectral resolution of light emanating from the array.

The optical reader also comprises a light source 28 which produces light of a suitable intensity and spectrum that may be variably attenuated by the transmission spectrum of the first material, or may excite the fluorescence of the first material, in the preferred embodiment. The light source 28 may comprise an LED (light emitting diode) or LED array, lamp, laser or other suitable light source and suitable optics to illuminate the array as required. The light source 28 constitutes a radiation source of optical radiation comprising at least one of infrared radiation, visible light and ultraviolet radiation.

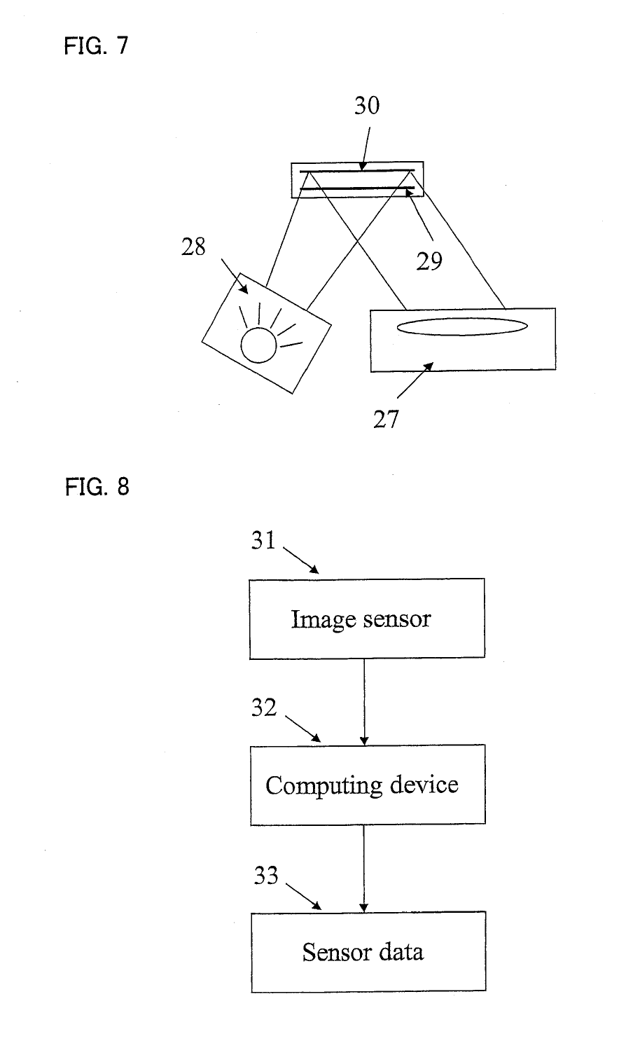

FIG. 7 illustrates a possible reflection optical geometry for interrogating the sensor chip. The front electrode 29 is transparent and the back electrode 30 is reflective. Either electrode may be covered with the first material. Light from the light source 28 is attenuated by the reflection spectrum of the first material or light excites the fluorescence of the first material. The image sensor 27 records an image of the sensor array. The optical geometries are not restricted to the two shown here and other suitable optical geometries may be used.

The light source 28 or the image sensor 27 or both may be scanning devices and may illuminate and image only a part of the array at any time.

FIG. 8 illustrates an image sensor 31 which forms part of an external reader device. The image sensor may be controlled by a computing device 32. The computing device instructs the image sensor to record one or more images of the sensor array, which may take the form of a video. The computing device then analyses the images of the array and calculates the sensor response 33 at each pixel. This information is then further used to determine the composition of the fluid as required.

### Embodiment 2

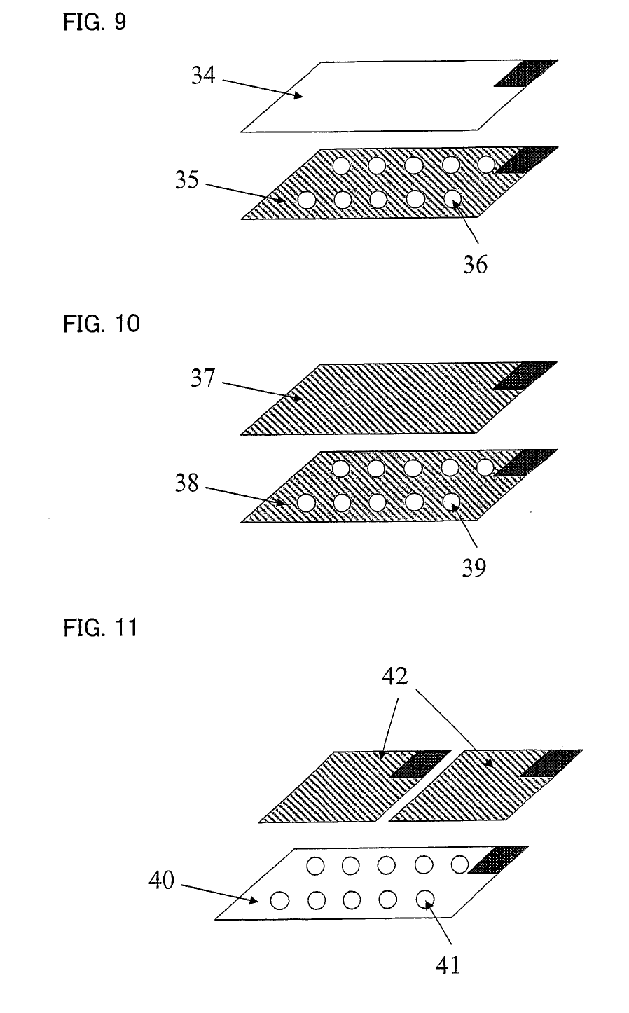

FIG. 9 illustrates the construction of a sensor chip. An electrode 34 is not coated with either the first or second material. An electrode 35 is coated with a layer of the first material. On top of the layer of the first material on the electrode 35 are deposited a number of islands 36 of the second material, forming sensor sites. It is clear from the equivalent circuits of FIG. 4 and FIG. 5 that the position of the second material in any sensor site does not alter the function of the sensor site.

### Embodiment 3

FIG. 10 illustrates the construction of a sensor chip. At least one of electrodes 37 and 38 is coated with the first material. At least one of the electrodes 37 and 38 has islands of the second material 39 deposited to form sensor sites. It is clear from the equivalent circuits of FIG. 4 and FIG. 5 that the position of the first material or second material in any sensor site does not alter the function of the sensor site.

### Embodiment 4

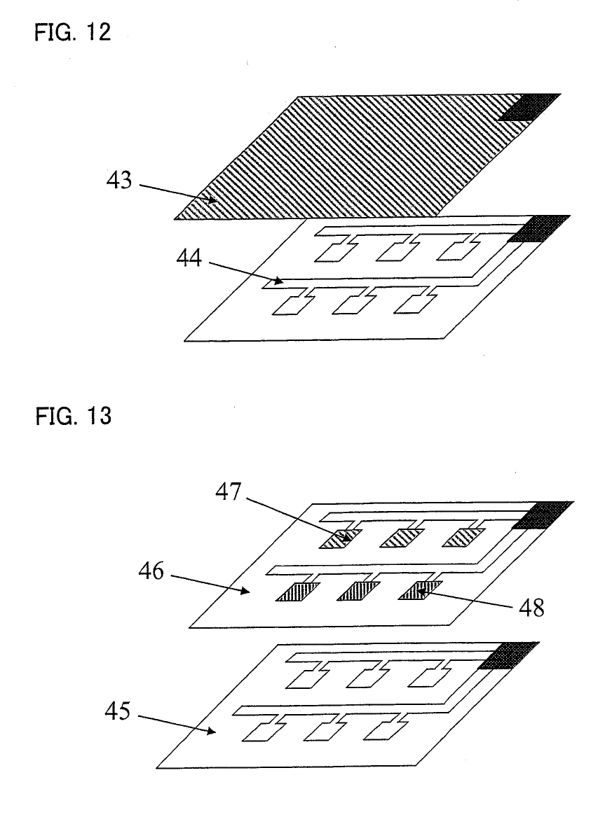

FIG. 11 illustrates the construction of a sensor chip. An electrode 40 comprises a single piece of conductive material and has islands of the second material 41 deposited on it to form sensor sites. Electrodes 42 comprise two or more separate electrodes. The electrodes 42 are coated in the first material. The exact composition of the first material layer on each of the electrodes 42 may be different.

As an alternative, the electrode 40 may be coated with the first material and the electrodes 42 may have islands of the second material deposited on them.

As an alternative, the islands of the second material may be deposited on top of the electrode or electrodes bearing the first material in either of the above alternatives.

### Embodiment 5

FIG. 12 illustrates the construction of a sensor chip. An electrode 43 is unpatterned and coated in the first material. An electrode 44 is patterned, using photolithography, mask evaporation, screen printing or another technique, to delimit the sensor sites. The second material is deposited at the delimited sensor sites on the electrode 44.

As an alternative, the electrode 43 bearing the first material may also be patterned to delimit pixels.

### Embodiment 6

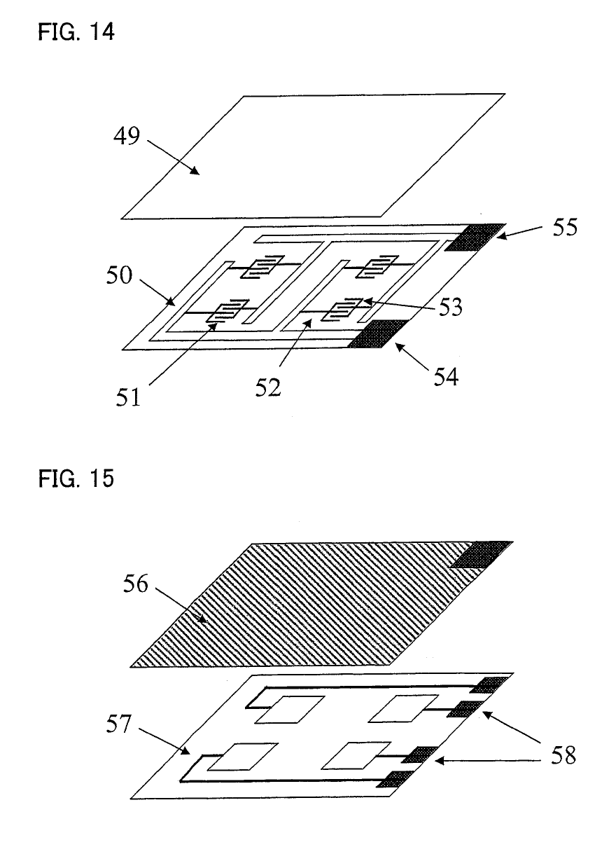

FIG. 13 illustrates the construction of a sensor chip. An electrode 45 is patterned to delimit sensor sites and the second material is deposited at the delimited sensor sites. An electrode 46 is patterned to delimit sensor sites. Two or more different first materials are coated on different sensor sites (for example 47 and 48).

### Embodiment 7

FIG. 14 illustrates the construction of a sensor chip. A plate 49 comprises a plate of glass, plastic or similar material. An electrode 50 is patterned to delimit sensor sites. Each sensor site 51 preferably comprises interdigitated electrodes. At each sensor site one electrode (for example 52) is coated with the first material. The other electrode (for example 53) has the second material deposited on it. The first electrode in this case may also have the second material deposited over the first material.

The electrodes bearing the first material 52 are connected together and connected to an off-chip contact 54. The electrodes bearing the second material 53 are connected together and connected to an off-chip contact 55.

The plate 49 and the electrode 50 may be held apart at a fixed distance by spacers of an inert plastic, by being held rigid in a frame or by any other method. The analyte-bearing fluid to be sensed is introduced between the electrode and plate.

Alternatively, the plate 49 may be omitted and the sensor chip may comprise only the electrode 50. The analyte-bearing fluid may be dropped onto the chip, the chip may be immersed in fluid, or other means for bringing the fluid and chip together may be employed.

### Embodiment 8

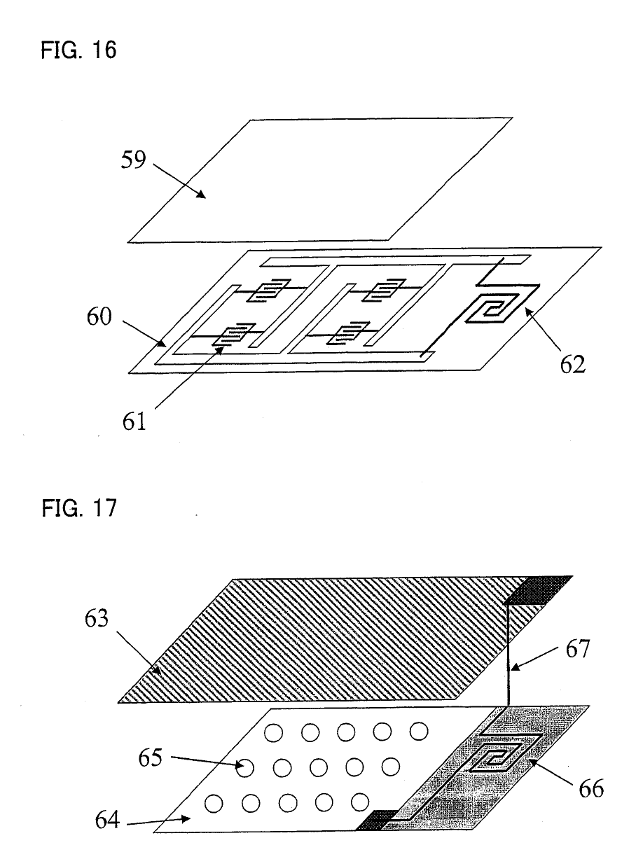

FIG. 15 illustrates the construction of a sensor chip. An electrode 56 is coated with the first material. An electrode 57 is patterned to delimit sensor sites. The second material is then deposited on the sensor sites. The sensor sites on the electrode 57 are connected to multiple off-chip interconnects 58. Each site may have its own interconnect or multiple sites may be connected to the same interconnect. The multiple interconnects permit different drive signals to be employed at different sensor sites.

As an alternative, the electrode 56 bearing the first material may also be patterned and have more than one off-chip interconnect.

### Embodiment 9

FIG. 16 illustrates the construction of a sensor chip. A plate 59 comprises a plate of glass, plastic or a similar material. An electrode 60 is patterned to delimit sensor sites. Each sensor site 61 preferably comprises of interdigitated electrodes. At each sensor site one electrode is coated with the first material. The other electrode has the second material deposited on it. The first electrode in this case may also have the second material deposited over the first material.

The electrode 60 has no off-chip electrical interconnects. Instead an aerial or antenna 62 is patterned onto or attached to the chip, for example in the form of a coil for inductive coupling. The aerial receives the drive signal and power from an external device by wireless means. Preferably, the chip is inductively coupled to the external device.

### Embodiment 10

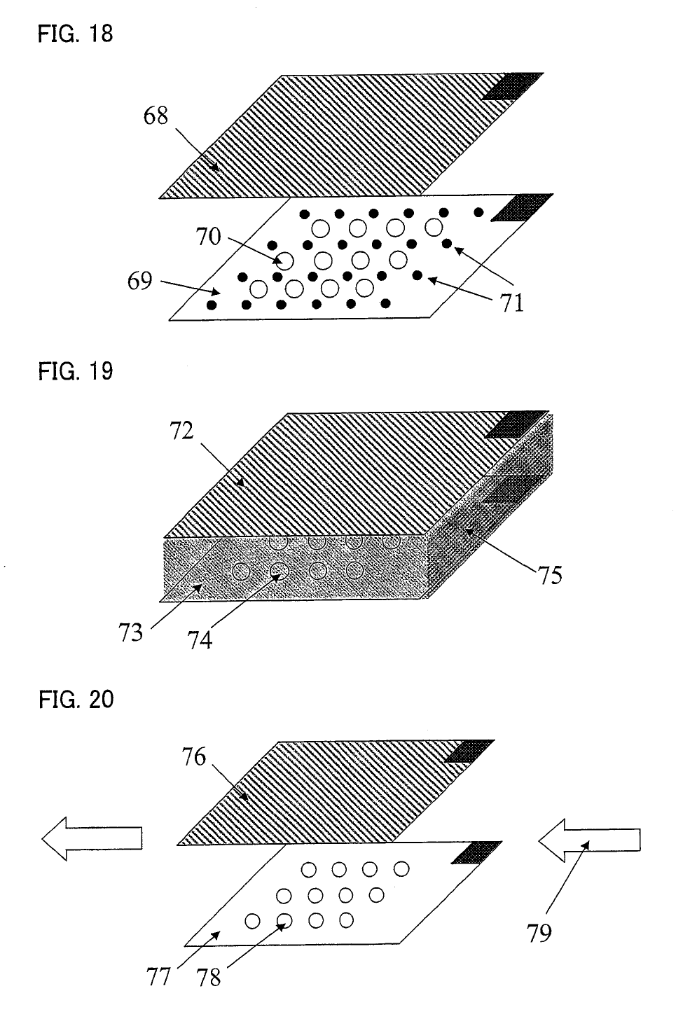

FIG. 17 illustrates the construction of a sensor chip. An electrode 63 is coated with the first material. An electrode 64 has islands 65 of the second material deposited upon it. The electrode 64 has no off-chip electrical interconnects. An aerial 66 receives the drive signal and power from an external device by wireless means. Preferably, the chip is inductively coupled to the external device.

A wire 67 connects one end of the aerial 66 to the other electrode 63. In this way, both electrodes receive the drive signal from the aerial. The wire 67 may be free, embedded in a plastic frame or in another position.

As alternatives, either or both of the electrodes 63 and 64 may be patterned and either or both may be coated with either the first material or the second material.

### Embodiment 11

FIG. 18 illustrates the construction of a sensor chip. An electrode 68 is coated with the first material. An electrode 69 has islands 70 of the second material deposited upon it. One or both electrodes are porous or contain a plurality of holes 71 in order that the analyte-bearing fluid may gain entrance to the chip interior.

Since the analyte-bearing fluid may gain entrance through the electrode 69, the edges of the electrodes 68 and 69 may be sealed together.

As alternatives, either or both of the electrodes 68 and 69 may be patterned and either or both may be coated with either the first material or the second material.

### Embodiment 12

FIG. 19 illustrates the construction of a sensor chip. An electrode 72 is coated with the first material. An electrode 73 has islands 74 of the second material deposited upon it.

The gap between the electrodes 72 and 73 is filled with a gel or solid 75 that is capable of retaining an electrolyte or that has electrolyte properties. The gel or solid may comprise materials including polyelectrolytes, sol-gel materials, polymer membranes and others. The presence of the gel or solid may allow airborne analytes to diffuse into the gel and to be detected by the sensor array.

As alternatives, either or both of the electrodes 72 and 73 may be patterned and either or both may be coated with either the first material or the second material.

### Embodiment 13

FIG. 20 illustrates the construction of a sensor chip for use in a fluid cell. An electrode 76 is coated with the first material. An electrode 77 has islands 78 of the second material deposited upon it.

The two electrodes may be held apart at a fixed distance by spacers of an inert plastic, by being held rigid in a frame or by any other method. The analyte-bearing fluid 79 to be sensed is caused to flow through the cell and passes over the sensor sites.

As alternatives, either or both of the electrodes 76 and 77 may be patterned and either or both may be coated with either the first material or the second material.

### Example 1

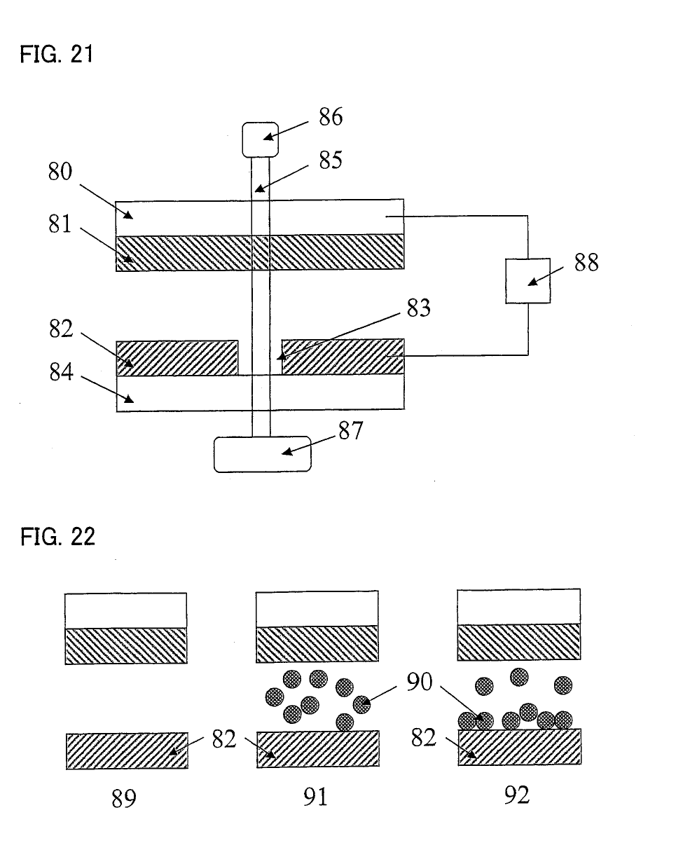

This example relates to the operation of a sensor pixel with an electrode coated with a first material. A sensor array may be considered as being built up from many of such pixels. FIG. 21 illustrates the design of the sensor pixel. The analyte-bearing fluid is contained between an electrode 80 made of indium tin oxide and an electrode 82 with a silver surface. The electrode 80 is transparent and the electrode 82 has a hole 83 machined in it. A glass plate 84 completes the pixel.

The electrode 80 is coated with a layer of a first material 81, comprising polyaniline (emeraldine salt—Sigma Aldrich). The electrode 82 has a silver surface which is the chemically-responsive second material in this pixel.

Red light 85 from an LED 86 is transmitted through the cell onto a photodiode 87 which measures the intensity of the transmitted light. Drive electronics 88 apply a square wave voltage of 200 mV (electrode 80 positive) between the electrodes at 3 Hz. The drive electronics 88 also measure the electrical impedance of the pixel.

The pixel is filled with an aqueous solution of 0.1 M phosphate buffer pH 4. During the experiment, a 5 μM solution of a proprietary chemical C1 is introduced. C1 is known to bind to the silver second material and cause a change in the electrical impedance of the electrode. FIG. 22 illustrates the electrode surface 82 before the chemical C1 (90) is introduced (89), just after C1 has been introduced (91) and a long time after C1 has been introduced where the reaction between C1 and the silver surface of the electrode 82 is complete (92). Increasing amounts of C1 build up at the surface of the electrode 82 until the reaction is complete, altering its electrical impedance.

The square wave voltage applied by the drive electronics 88 causes a current to flow through the cell as the electrodes charge and discharge. The charge carried by this electrical current causes the first material to alter its colour and therefore its transmission spectrum. This change in transmission spectrum causes a change in the intensity of the light 85 falling on the photodiode 87.

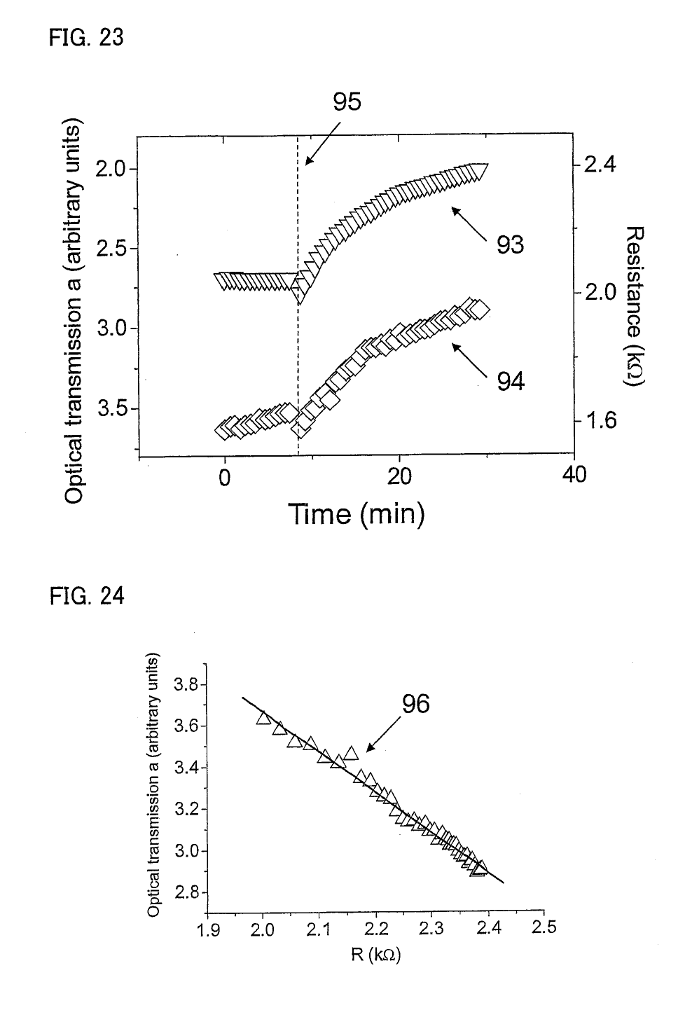

Curve 93 in FIG. 23 shows the electrical resistance R of the pixel during the experiment as measured by the drive electronics 88. This is calculated assuming the pixel to show an impedance of the form:

$$Z = R + \frac{1}{i ω C} \qquad ( Eqn 1 )$$

where Z is the impedance, C is the capacitance and ω is the frequency of the drive signal.

Curve 94 in FIG. 23 shows the in-phase component a of the light intensity recorded by the photodiode 87 during the experiment where the total light intensity is given:

I=a cos(ωt)+b sin(ωt) (Eqn 2)

In FIG. 23, at times to left of the line 95, there is only phosphate buffer in the sensor pixel and the resistance and light in-phase data do not change significantly with time. To the right of the line 95, the chemical C1 has been introduced and both the pixel resistance R (Eqn 1) and light intensity a (Eqn 2) change with a similar characteristic shape. This demonstrates that the reaction of C1 with the silver second material can be monitored by the optical transmission of the first material instead of measuring the cell current electrically.

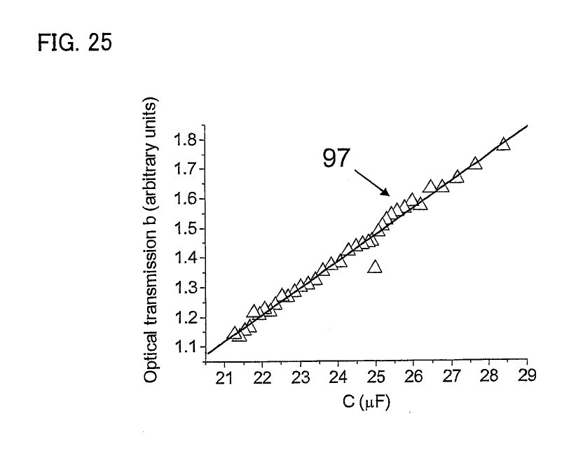

In FIG. 24, curve 96 shows that the in-phase component of the optical transmission signal a (Eqn 2) from the first material corresponds to the electrical resistance R of the pixel (Eqn 1). In FIG. 25, curve 97 shows that the out-of-phase optical transmission signal b (Eqn 2) corresponds to electrical capacitance C of the cell (Eqn 1). The binding reaction between C1 and the silver second material can clearly be monitored by recording the optical properties of the first material instead of recording the electrical properties of the pixel.

The present invention is not limited to the description of the embodiments above, but may be altered by a skilled person within the scope of the claims. An embodiment based on a proper combination of technical means disclosed in different embodiments is encompassed in the technical scope of the present invention.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A sensor for sensing at least one analyte of a sample, comprising at least one first electrode, at least one second electrode, and at least one sensor site, said at least one sensor site comprising first and second materials disposed between said at least one first electrode and said at least one second electrode, said at least one first and second electrodes being arranged to receive electricity, said second material being arranged to contact said sample and to vary, in response to said received electricity, one of a charge passing through and a potential across said second material in accordance with one of a presence and a quantity of said at least one analyte in said sample, said first material having an optical property whose value is a function of one of a charge passing through and a potential across said first material.

2. A sensor as claimed in claim 1, in which said first and second materials are electrically in series between said at least one first and second electrodes.

3. A sensor as claimed in claim 1, in which at least one of said at least one first electrode and second said at least one electrode is transparent.

4. A sensor as claimed in claim 1, comprising a wireless electricity receiver connected to said at least one first electrode and said at least one second electrode.

5. A sensor as claimed in claim 4, in which said wireless electricity receiver comprises a coil for inductive coupling to an electricity source.

6. A sensor as claimed in claim 1, in which said sample is a fluid sample.

7. A sensor as claimed in claim 1, in which said at least one sensor site comprises a plurality of sensor sites.

8. A sensor as claimed in claim 7, in which said at least one analyte comprises a plurality of different analytes and said plurality of sensor sites are sensitive to said plurality of different analytes.

9. A sensor as claimed in claim 7, in which said at least one first electrode comprises a plurality of first electrodes and at least some of said plurality of first electrodes are connected together.

10. A sensor as claimed in claim 9, comprising a common unpatterned electrode having portions, and in which said at least some of said plurality of first electrodes comprise said portions of said common unpatterned electrode.

11. A sensor as claimed in claim 10, in which one of said first and second materials comprises a layer formed on said first common unpatterned electrode.

12. A sensor as claimed in claim 11, in which said at least one sensor site comprises a plurality of sensor sites and another of said first and second materials is formed as islands defining said plurality of sensor sites on said first material.

13. A sensor as claimed in claim 1, in which said first and second electrodes are interdigitated at each said at least one sensor site.

14. A sensor as claimed in claim 13, in which said first and second electrodes are coated with said first and second materials, respectively.

15. A sensor as claimed in claim 1, in which said first and second electrodes are spaced apart to provide access to said second material for said sample.

16. A sensor as claimed in claim 15, in which at least one of said at least one first and second electrodes defines holes for passage of said sample.

17. A sensor as claimed in claim 15, comprising one of a gel and a solid disposed between said at least one first electrode and at least one second electrode for permitting diffusion of said at least one analyte.

18. A combination of; a sensor for sensing at least one analyte of a sample, comprising at least one first electrode, at least one second electrode, and at least one sensor site, said at least one sensor site comprising first and second materials disposed between said at least one first electrode and said at least one second electrode, said at least one first and second electrodes being arranged to receive electricity, said second material being arranged to contact said sample and to vary, in response to said received electricity, one of a charge passing through and a potential across said second material in accordance with one of a presence and a quantity of said at least one analyte in said sample, said first material having an optical property whose value is a function of one of a charge passing through and a potential across said first material; and an optical reader for reading said value of said optical property.

19. A combination as claimed in claim 18, in which said optical reader comprises a radiation source for irradiating said first material with optical radiation and a detector for detecting said value of said optical property.

20. A combination as claimed in claim 19, in which said optical radiation is at least one of infrared radiation, visible light and ultraviolet radiation.
